(19) United States
(12) Patent Application Publication
(10) Pub. No.: US 2026/0026339 A1
(43) Pub. Date: Jan. 22, 2026

(54) CAPACITOR WITH LOW PARASITIC CAPACITANCE, AND MANUFACTURING METHOD THEREFOR

(71) Applicant: STMicroelectronics International N.V., Geneva (CH)

(72) Inventors: Vincenzo PALUMBO, Milano (IT); Federica OTTOGALLI, Gorgonzola (IT); Roberto STELLA, Como (IT)

(73) Assignee: STMicroelectronics International N.V., Geneva (CH)

(21) Appl. No.: 19/258,360

(22) Filed: Jul. 2, 2025

(30) Foreign Application Priority Data
Jul. 17, 2024 (IT) 102024000016540

(51) Int. Cl. H01L 23/522

(52) U.S. Cl. CPC H01L 23/5223; H01L 23/5225

(57) ABSTRACT

Electronic device including a primary capacitor extending on a semiconductor body accommodating a floating P-well and an N-type buried layer, to provide a P-N junction. This structure introduces a junction capacitance in series with the parasitic capacitance that the primary capacitor forms with the semiconductor body, effectively lowering the overall parasitic capacitance of the electronic device.

### BACKGROUND

### Technical Field

The present disclosure relates to an electronic device and a manufacturing method therefor, in particular an electronic device with low parasitic capacitances.

### Description of the Related Art

Galvanic isolation is known for isolating different functional sections of an electrical or electronic system by avoiding direct conduction paths between different sections. In monolithic integrated circuits, galvanic isolation is obtained in particular with a capacitive or inductive coupling, wherein electrical signals are transmitted capacitively or inductively between the different functional sections of the system through a dielectric layer.

Parasitic capacitances are the main source of signal degradation in the event of transmission through galvanically isolated devices, since the quality of the transmitted signal strongly depends on the value of parasitic capacitance. High values of parasitic capacitance determine greater degradation of the transmitted signal.

FIG. 1 schematically illustrates a portion of an electronic device 10 which includes a galvanic isolator 11, in a triaxial system of axes x, y, z orthogonal to each other, and in a cross-section view on the xz plane.

The electronic device 10 includes a semiconductor body 100 which in turn comprises a substrate 102 for example of semiconductor material, more in particular of a material from among silicon (Si), silicon carbide (SiC), sapphire (Al₂O₃), GaN; and an epitaxial layer 104, of semiconductor material, for example Si or SiC, that is P-type doped, extending on a face 102a of the substrate 102 and having a surface 104a. Furthermore, a P-well region 106, having a concentration of doping species higher than the concentration of doping species of the epitaxial layer 104, extends in the epitaxial layer 104 at the surface 104a; and an insulating layer 107, provided with openings having the surface 104a exposed therethrough, extends in the P-well region 106 at the surface 104a.

The electronic device 10 further includes a dielectric layer 108 extending above the semiconductor body 100, in particular on the surface 104a. The galvanic isolator 11, here of the capacitive type, comprising a bottom metal layer 110, a top metal layer 112 and an intermediate dielectric layer 114 extending between the bottom metal layer 110 and the top metal layer 112, extends on the dielectric layer 108. The bottom metal layer 110 and the top metal layer 112 form the plates of a capacitor 111 schematized in FIG. 1, and the intermediate dielectric layer 114 is the dielectric of this capacitor 111.

A parasitic capacitance 109 formed between the bottom metal layer 110 and the semiconductor body 100, where the insulating layer 107 is absent, is also schematically represented in FIG. 1. The value of the parasitic capacitance 109 depends, at least in part, on the thickness of the dielectric layer 108 and on the material of the dielectric layer 108.

Solutions known to the Applicant, to lower the value of the parasitic capacitance, envisage increasing the thickness of the dielectric layer 108 and/or increasing the distance between the bottom metal layer 110 and the insulating layer 107 (for example forming the metal layer 110 at a higher metal level). However, both these solutions introduce different complexities in the post-production processes such as for example an increase in the aspect ratio of any metal contacts formed through the dielectric layer 108 (in the event that the thickness of the dielectric layer 108 is increased) and/or an increase in the number of metal levels that need to be deposited (in the event that the metal layer 110 is formed at a higher metal level).

The aforementioned technical issue occurs, in general, in any electronic device that has a capacitor structure on a semiconductor body (instead of, or in addition to, the galvanic isolator previously mentioned), and for which it is desired or appropriate to lower a parasitic capacitance between this capacitor structure and the underlying semiconductor body.

The need is therefore felt to provide an electronic device and a manufacturing method therefor, such as to overcome the drawbacks of the prior art.

### BRIEF SUMMARY

The present disclosure relates to an electronic device and a manufacturing method therefor. The electronic device includes a primary capacitor extending on a semiconductor body accommodating a floating P-well and an N-type buried layer, to provide a P-N junction. This structure introduces a junction capacitance in series with the parasitic capacitance that the primary capacitor forms with the semiconductor body, effectively lowering the overall parasitic capacitance of the electronic device.

### BRIEF DESCRIPTION OF THE SEVERAL VIEWS OF THE DRAWINGS

For a better understanding of the present disclosure, some embodiments thereof are now described, purely by way of non-limiting example, with reference to the attached drawings, wherein:

FIG. 1 illustrates, in sectional view, an electronic device with galvanic isolator;

FIG. 2 illustrates, in sectional view, an electronic device with galvanic isolator, according to one embodiment;

FIG. 3 illustrates, in a top view, the electronic device of FIG. 2;

FIGS. 4A-4D illustrate, limitedly to elements useful for understanding the invention, structural variants of the electronic device of FIG. 2, according to respective embodiments;

FIGS. 5-7 illustrate, in sectional view, an electronic device with galvanic isolator, according to respective further embodiments;

FIG. 8 illustrates, in sectional view, an electronic device with metal-oxide-metal capacitor, according to a further embodiment; and

FIG. 9 illustrates an integrated circuit which comprises the electronic device of one of the embodiments of FIGS. 2 and 5-7 and the electronic device of FIG. 8.

### DETAILED DESCRIPTION

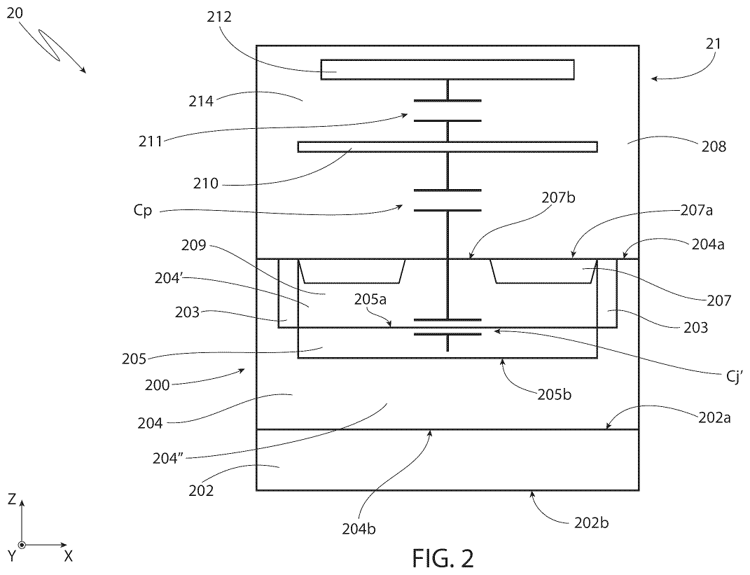

FIG. 2 illustrates a portion of an electronic device 20, comprising a galvanic isolation module (or galvanic isolator) 21, according to one embodiment. The electronic device 20 is represented in a triaxial system of axes x, y, z orthogonal to each other.

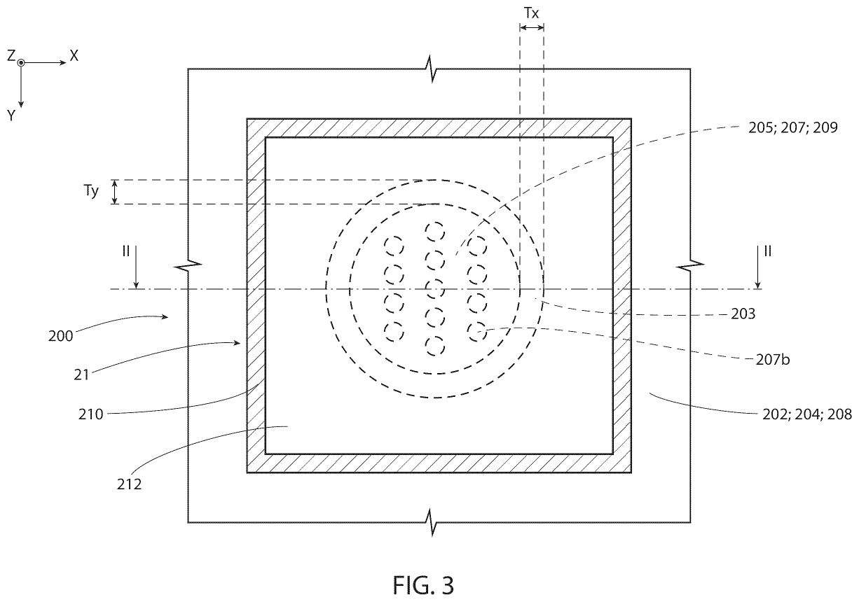

FIG. 3 illustrates the device of FIG. 2 in a top view, on the xy plane. FIG. 2 is a lateral sectional view, on the xz plane, along the scribe line II-II of FIG. 3.

The electronic device 20 includes a solid body 200, comprising: a substrate 202, having a first and a second surface 202a, 202b, opposite to each other along the z axis; and a structural layer 204, extending on the surface 202a of the substrate, and having a first and a second surface 204a, 204b opposite to each other along the z axis, and wherein the second surface 204b faces the first surface 202a.

The substrate 202 is in particular of semiconductor material, such as for example silicon (Si), silicon carbide (SiC), or others. The structural layer 204 is in particular of semiconductor material, for example silicon (Si) or silicon carbide (SiC), for example grown epitaxially on the substrate 202. In one embodiment, the structural layer 204 comprises a plurality of superimposed layers, for example a plurality of layers of semiconductor material. In a further embodiment, the structural layer 204 is a single layer.

The solid body 200 may alternatively be of the SOI (“Silicon Over Insulator”) type.

In the example illustrated in FIG. 2, the solid body 200 is delimited at the bottom by the second surface 202b of the substrate 202 and at the top by the first surface 204a of the structural layer 204.

An insulating layer 207 extends in the solid body 200 (in particular, in the structural layer 204) at the first surface 204a. The insulating layer 207 is patterned so as to have openings or trenches 207a having the surface 204a of the structural layer 204 exposed therethrough.

Even more in particular, the insulating layer faces the first surface 204a and comprises one own surface 207a coplanar with the first surface 204a of the structural layer 204. The insulating layer is for example formed through masked oxidation of the structural layer 204 or, alternatively, by steps, successive to each other, of etching the structural layer 204 and depositing silicon oxide within the etched regions, up to filling them. The structural layer 204 has a first electrical conductivity, for example of P-type.

The structural layer 204 has, for example, a thickness along the z axis comprised between 5 μm and 25 μm (range boundaries included), for example equal to 15 μm. The structural layer 204 has, for example, a dopant concentration comprised between 10¹⁴ at/cm³ and 10¹⁶ at/cm³ (range boundaries included) for example equal to 10¹⁵ at/cm³.

The insulating layer 207 has, for example, a thickness along the z axis comprised between 0.1 μm and 0.5 μm (range boundaries included), for example equal to 0.3 μm.

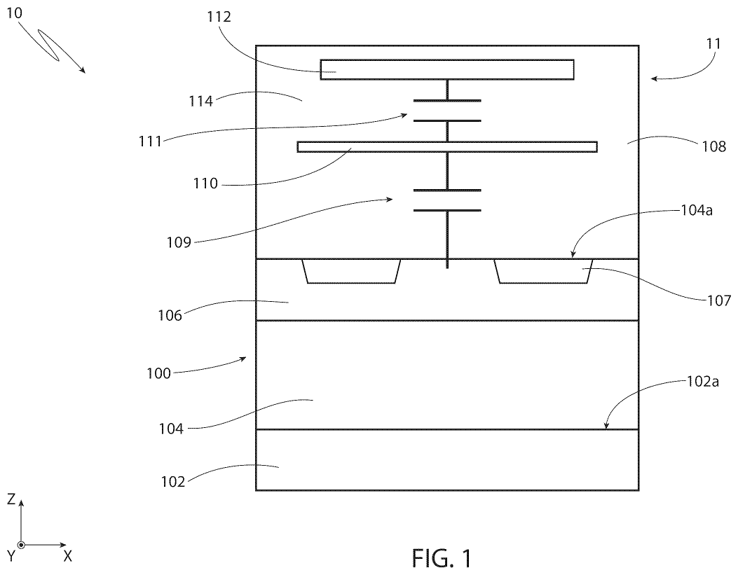

Similarly to what has been described with reference to FIG. 1, the electronic device 20 further includes a dielectric layer 208 extending above the solid body 200, in particular on the surface 204a. The dielectric layer 208 has a thickness, along the z axis, for example comprised between 2 and 5 μm. The galvanic isolator 21, here of the capacitive type, comprising a bottom metal layer 210, a top metal layer 212 and an intermediate dielectric layer 214 extending between the bottom metal layer 210 and the top metal layer 212, extends on the dielectric layer 208. The intermediate dielectric layer 214 has a thickness, along the z axis, for example comprised between 8 and 15 μm. The bottom metal layer 210 and the top metal layer 212 form the plates of a capacitor 211 illustrated schematically in FIG. 2, and the intermediate dielectric layer 214 is the dielectric interposed between the plates of this capacitor 211. A parasitic capacitance Cp formed between the bottom metal layer 210 and the solid body 200 (where the insulating layer 207 is absent, in particular at the openings through the insulating layer 207) is also shown schematically in FIG. 2. The value of Cp is in the range 10-1000 fF.

Furthermore, a buried region 205 extends within the structural layer 204, at a distance (along the z axis) from the insulating layer 207. An intermediate portion 204′ of the structural layer 204 extends between the insulating layer 207 and the buried region 205. A further intermediate portion 204″ of the structural layer 204 extends between the buried region 205 and the second surface 204b of the structural layer 204. The buried region 205 has a second electrical conductivity (N) opposite to the first electrical conductivity (P). The intermediate portion 204′ has the first electrical conductivity (P). The intermediate portion 204″ has the first electrical conductivity (P).

The buried region 205 therefore extends completely within the structural layer 204, between the insulating layer 207 and the substrate 202. The buried region 205 lies on a plane substantially parallel to the xy plane.

The buried region 205 is delimited by a top surface 205a and a bottom surface 205b, opposite to each other along the z axis.

The distance, along the z axis, between the surface 204a and the top surface 205a of the buried region 205 is comprised between 0.5 μm and 2 μm, e.g., about 1 μm.

The buried region 205 has, for example, a thickness comprised between the surfaces 205a and 205b and along the z axis, comprised between 0.5 μm and 2 μm (range boundaries included), for example 1 μm. The buried region 205 has, for example, a dopant concentration comprised between 10¹⁶ at/cm³ and 10¹⁸ at/cm³ (range boundaries included), for example 10¹⁷ at/cm³.

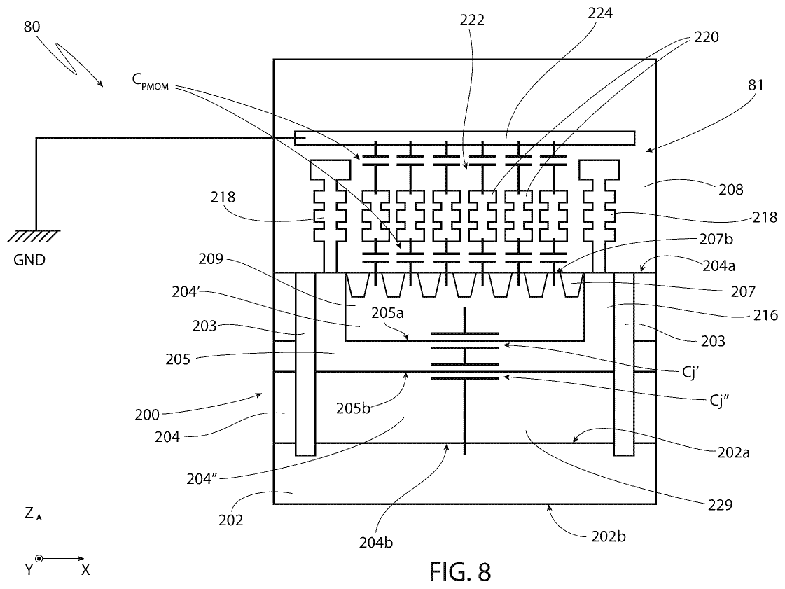

In one embodiment, the buried region 205 is electrically floating, i.e., it is not biased or biasable. Alternatively (as for example illustrated in FIG. 8, but not limitedly to this embodiment), electrical contacts are envisaged (e.g., type-N implants or conductive trenches) which from the surface 204a extend in the structural layer 204 up to reaching and electrically contacting the buried region 205. Such electrical contacts are for providing an electrical path for biasing the buried region 205.

The electronic device 20 further comprises a trench 203 which extends in depth in the solid body 200, along the direction of the z axis, starting from the first surface 204a, up to reaching the buried region 205; furthermore, the trench 203 is in direct contact with the buried region 205. Furthermore, in plan view on the xy plane, the trench 203 completely surrounds the buried region 205, as may be appreciated from the plan view of FIG. 3. The trench 203 and the buried region 205 are mutually arranged in such a way as to electrically insulate the portion 204/209 surrounded, or externally delimited, by the trench 203 and the buried region 205 with respect to the rest of the structural layer 204.

The trench 203 is for example of the DTI (Deep Trench Isolation) type, formed in a per se known manner.

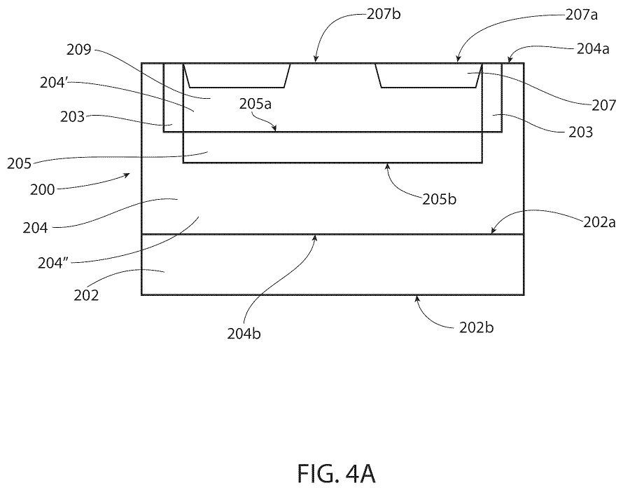

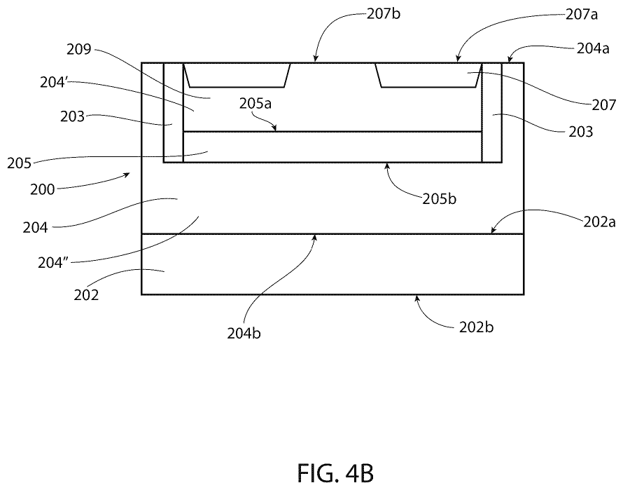

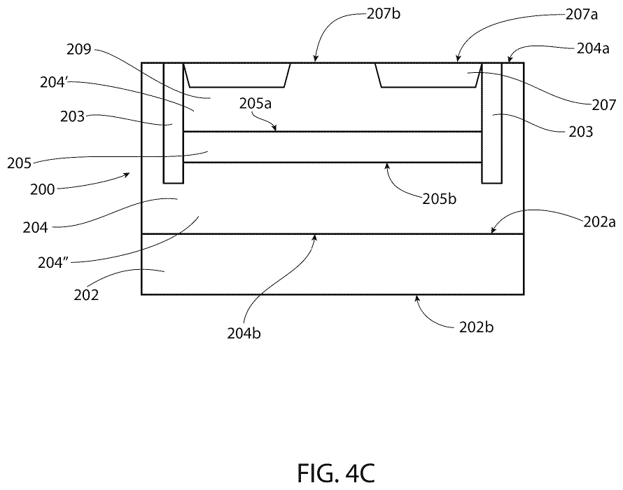

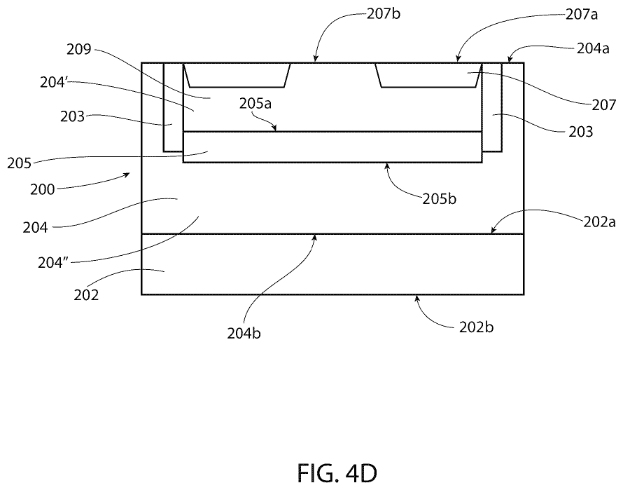

The trench 203 extends along the z axis up to a depth equal to the depth of the top surface 205a of the buried region 205, reaching the buried region 205 at the top surface 205a of the buried region 205 or in a position laterally adjacent to the top surface 205a of the buried region 205. In respective embodiments, the trench 203 extends: (FIG. 4A) in the structural layer 204 up to a depth equal to the depth of the top surface 205a of the buried region 205; or (FIG. 4B) in the structural layer 204 up to a depth equal to the depth of the bottom surface 205b of the buried region 205; or (FIG. 4C) in the structural layer 204 up to a depth greater than the depth of the bottom surface 205b of the buried region 205; or (FIG. 4D) in the structural layer 204 up to a depth comprised between the depth of the top surface 205a and the depth of the bottom surface 205b of the buried region 205.

The trench 203 accommodates therewithin one or more layers of insulating material (such as for example silicon oxide or silicon nitride), or of N-type doped polysilicon electrically insulated from the structural layer 204 by a layer of insulator such as for example silicon oxide. In one embodiment, the trench 203 is completely filled by said one or more layers of insulating material and/or polysilicon. In a further embodiment, the trench 203 is partially filled by said one or more layers of insulating material and/or polysilicon. Regardless of whether the trench 203 is completely or partially filled, in the event of filling by a plurality of layers, these layers may be superimposed on each other along the direction of the z axis, or along the direction of the x axis (similarly, y axis) covering the internal walls of the trench 203.

The thickness Tx of the trench 203, along the x axis, is comprised between 1 μm and 3 μm. The thickness Ty of the trench 203, along the y axis, is comprised in the same range as Tx.

The trench 203 is configured to delimit at least one sub-portion 209 of the intermediate portion 204′ electrically insulated from the intermediate portion 204″. In one embodiment, the spatial extension (e.g., area and/or volume) of the sub-portion 209 and the intermediate portion 204′ coincide. To this end, the trench 203 extends in direct lateral contact with the buried region 205, along the entire perimeter of the buried region 205.

The sub-portion 209 has, for example, a thickness along the z axis comprised between 0.5 μm and 2 μm (range boundaries included), for example 1 μm. The sub-portion 209 has, for example, a dopant concentration comprised between 10¹⁴ at/cm³ and 10¹⁶ at/cm³ (range boundaries included), for example 10¹⁵ at/cm³.

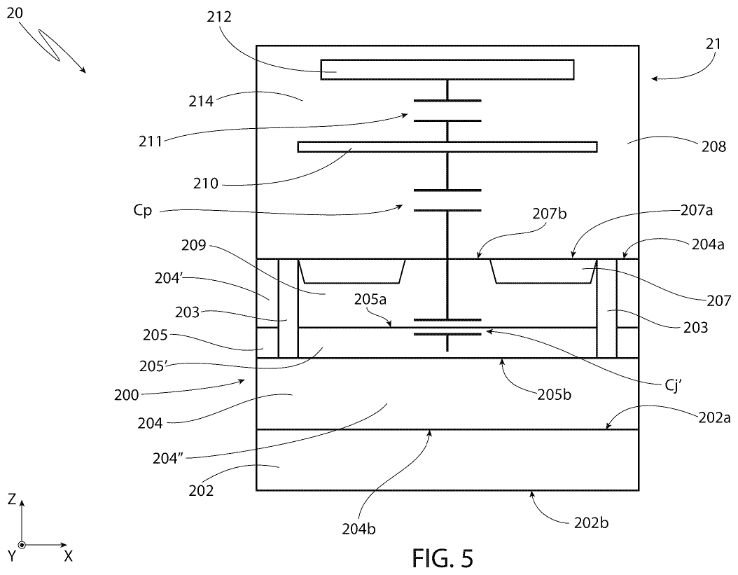

In a further embodiment, FIG. 5, the spatial extension (e.g., area and/or volume) of the sub-portion 209 is smaller than the corresponding spatial extension (e.g., area and/or volume) of the intermediate portion 204′. To this end, the trench 203 extends in direct contact with the buried region 205, at least partially or completely through the buried region 205. In this embodiment, the trench 203 delimits or completely surrounds a sub-portion 205′ of the buried region 205. Exemplarily, the spatial extension of the sub-portion 205′, in terms of area on the xy plane, is comprised between 0.01 mm² and 0.1 mm², for example 0.03 mm².

In both embodiments of FIGS. 2 and 5, the sub-portion 209 is electrically floating, i.e., electrically insulated from the rest of the structural layer 204 by the trench 203 (which provides lateral insulation) and the buried region 205 (which provides bottom insulation).

According to various embodiments of the present disclosure, a first capacitance Cj′ is thus generated at the interface between the sub-portion 209 and the buried region 205. The first capacitance Cj′ is formed spontaneously due to the presence of the P-N junction between the buried region 205 (N-type) and the sub-portion 209 of the structural layer 204 (P-type). Since the first capacitance Cj′ is a junction capacitance that is generated in the absence of a bias of the buried region 205 and/or the sub-portion 209, its value is lower than the value of the capacitance Cp, for example the value of Cj′ is in the range 10-100 fF.

By modulating the doping value of the sub-portion 209 (similarly, of the intermediate portion 204′) and of the buried region 205, the width of the depleted region at the interface between the sub-portion 209 (similarly, the intermediate portion 204′) and the buried region 205 may be consequently modulated. In particular, the size of the depleted region increases by lowering the doping value. In one embodiment, the size of the depleted region, and therefore the value of capacitance Cj′ may thus be adjusted, without applying an external bias.

The first capacitance Cj′ is in series electrical connection with the parasitic capacitance Cp and lowers the total parasitic capacitance value of the electronic device 20.

When the buried region 205 is biasable from the outside (e.g., as in FIG. 8, but not limitedly to this embodiment), the buried region 205 may be reversely biased so as to further decrease the value of capacitance Cj′.

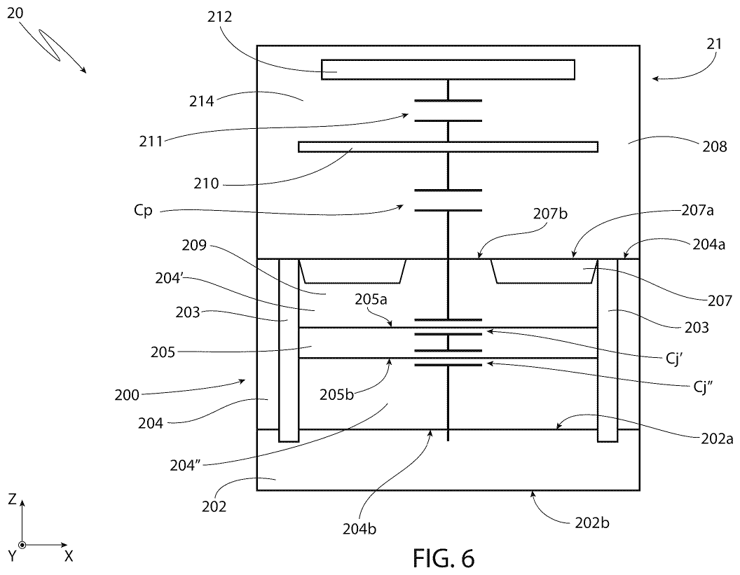

With reference to FIG. 6, the trench 203 extends throughout the entire thickness of the structural layer 204, up to reaching the second surface 204b of the structural layer 204. In one embodiment, the trench 203 extends at least in part in the substrate 202. In the embodiment of FIG. 6, the trench 203 extends adjacent to or in direct contact with or throughout the entire thickness of the buried region 205.

The trench 203 of FIG. 6 is configured to delimit at least one sub-portion 229 of the intermediate portion 204″. In one embodiment, the spatial extension (e.g., area and/or volume) of the sub-portion 229 and the intermediate portion 204″ coincide. To this end, the trench 203 extends in direct lateral contact with the buried region 205, along the entire perimeter of the buried region 205.

The sub-portion 229 has, for example, a thickness along the z axis comprised between 10 μm and 20 μm (range boundaries included), for example 14 μm. The sub-portion 229 has, for example, a dopant concentration comprised between 10¹⁴ at/cm³ and 10¹⁶ at/cm³ (range boundaries included), for example 10¹⁵ at/cm³.

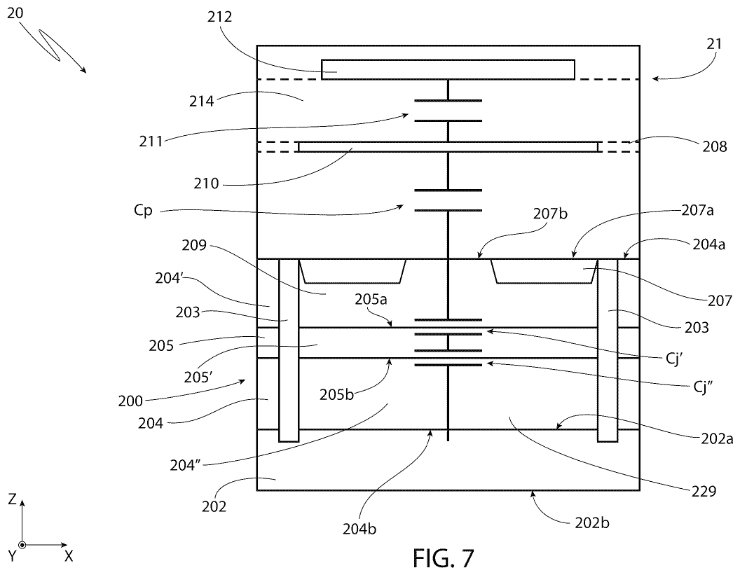

In a further embodiment, FIG. 7, the spatial extension (e.g., area and/or volume) of the sub-portion 229 is lower than the corresponding spatial extension (e.g., area and/or volume) of the intermediate portion 204″. To this end, the trench 203 extends completely through the buried region 205, similarly to what has been illustrated in FIG. 5.

The sub-portion 209 is electrically floating, i.e., electrically insulated from the rest of the structural layer 204 (and in particular from the sub-portion 229 or intermediate portion 204″) by the trench 203 and by the buried region 205.

According to various embodiments of the present disclosure, a second capacitance Cj″ is thus generated at the interface between the sub-portion 229 and the buried region 205. The second capacitance Cj″ is formed spontaneously due to the presence of the P-N junction between the buried region 205 (N-type) and the sub-portion 229 of the structural layer 204 (P-type). Similarly to what has been described with reference to the first capacitance Cj′, the second capacitance Cj″ is also a junction capacitance which is generated in the absence of a bias of the buried region 205 and/or of the sub-portion 229, and its value is lower than the value of the capacitance Cp; for example the value of Cj″ is in the range 10-100 fF.

When the buried region 205 is biasable from the outside (e.g., as in FIG. 8, but not limitedly to this embodiment), the buried region 205 may be reversely biased so as to further decrease both the value of capacitance Cj′ and the value of capacitance Cj “. By modulating the doping value of the sub-portion 229 (similarly, of the intermediate portion 204”) and of the buried region 205, the amplitude of the depleted region may be consequently modulated at the interface between the sub-portion 229 (similarly, the intermediate portion 204″) and the buried region 205. In particular, the size of the depleted region increases by lowering the doping value. The size of the depleted region, and therefore the value of capacitance Cj″, may thus be adjusted, without applying an external bias.

The second capacitance Cj″ is in series electrical connection with the first capacitance Cj′ and with the parasitic capacitance Cp, so as to further lower the total parasitic capacitance value of the electronic device 20.

FIG. 8 illustrates a portion of an electronic device 80 including at least one Metal-Oxide-Metal (MOM) type capacitor 81, according to a further embodiment. The electronic device 80 is represented in a triaxial system of axes x, y, z orthogonal to each other. In FIG. 8, elements of the electronic device 80 which are in common with the electronic device 20 of FIGS. 2, 5-7 are indicated with the same reference numerals and are not further described.

The electronic device 80 includes one or more patterned metal structures 220 that extend in the dielectric layer 208 at a distance from the first surface 204a, defining one or more MOM capacitors 81 in a per se known manner.

The MOM capacitor 81 is formed by one or more metal layers in the dielectric layer 208, arranged in such a way as to form a lateral capacitive coupling (that is intra-layer) that produces the desired capacitance. To increase the capacitance density, multiple metal layers may be parallel connected by vias, forming a vertical metal wall or mesh 222, as represented in FIG. 8 according to a non-limiting embodiment.

The device 80′ further comprises a shield layer 224, of conductive material, in particular metal, extending in the dielectric layer 208 above, and electrically insulated from, the vertical metal mesh 222. The shield layer 224 is coupled to a reference voltage terminal, in particular ground voltage GND. The shield layer 224 has the function of shielding the circuitry in proximity to the GI from surface electric fields, which may assume high values.

Parasitic capacitances CpMOM are establish between the vertical metal mesh 222 and the shield layer 224 and between the vertical metal mesh 222 and the solid body 200 (in particular between the vertical metal mesh 222 and the structural layer 204 where the insulating layer 207 is not present).

The electronic device 80 includes at least one conductive region 216 that extends in depth in the structural layer 204, along the z-axis direction, starting from the first surface 204a, up to reaching the buried region 205. The conductive region 216 is in electrical contact with the buried region 205. The conductive region 216 extends in particular in the first portion 204′/209 and, even more in particular, is surrounded by the trench 203 in plan view on the xy plane. In a non-limiting embodiment, the conductive region 216 has, in view on the xy plane, a ring shape.

The conductive region 216 is for example formed by implant of doping species having the second electrical conductivity (N).

The device 80 further includes one or more electrical contacts 218, which extend in the dielectric layer 208 reaching and electrically contacting the conductive region 216 at the first surface 204a. The one or more electrical contacts 218 are for providing an electrical bias to the buried region 205 through the conductive region 216. In detail, a reverse bias, for example with a value of 5-30 V, is applied to the junctions between the buried region 205 and the portion 209, and between the buried region 205 and the portion 229. Alternatively, the aforementioned junctions may be left floating.

The capacitance Cj′ is in series with the parasitic capacitances CpMOM. The capacitance Cj″, when present in the respective embodiments, is also in series with the parasitic capacitances CpMOM. In use, biasing the buried region 205 allows the value of the capacitances Cj′ and Cj″ to be further lowered.

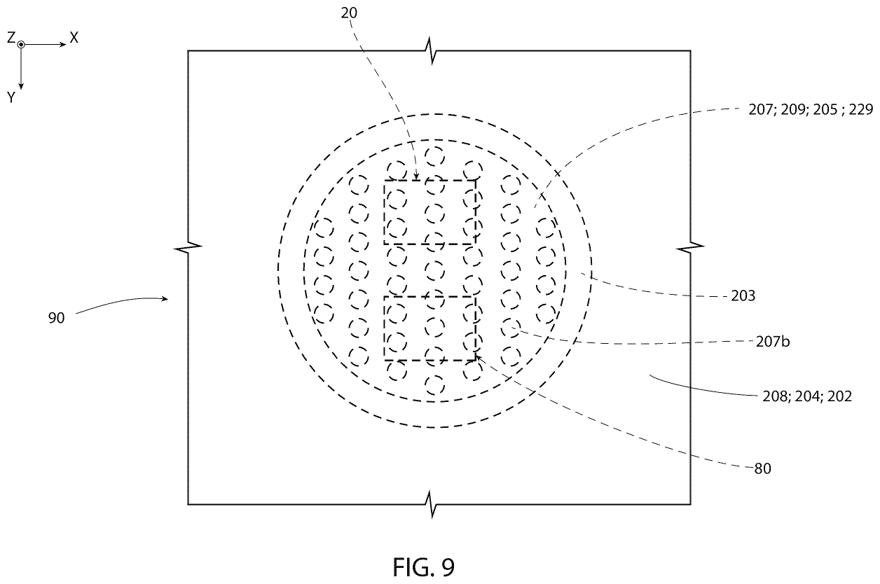

One embodiment of the present disclosure, schematically illustrated in FIG. 9 in top view on the xy plane of the triaxial reference system x, y, z, shows a portion of an integrated circuit 90 which accommodates the electronic device 80 (with MOM capacitor) and the electronic device 20 (with galvanic isolation module 21, according to any of the previously described embodiments). Both electronic devices 20 and 80 are implemented in the same solid body 200. The trench 203 surrounds both electronic devices 20 and 80. The metal layer 210 of the device 20 is, in one example embodiment, at the same metal level as the shield layer 224.

The various embodiments of the present disclosure finds application, in general, in any electronic device that has a capacitor structure on a solid body (instead of, or in addition to, the previously described galvanic isolator), and for which it is desired or appropriate to lower a parasitic capacitance between this capacitor structure and the underlying solid body.

The various embodiments of the present disclosure also finds application in an electronic device which has a metal structure or region (for example, a line for carrying an electrical signal) buried in the dielectric layer which extends above the solid body, and for which it is desired or appropriate to lower a parasitic capacitance between this metal region and the underlying solid body.

Furthermore, for all the embodiments previously described, the N and P electrical conductivities may be reversed (e.g., the structural layer 204 is of N-type and the buried region 205 is of P-type).

An electronic device (20; 80), may be summarized as including: a semiconductor body (200; 204), having a first surface (204a); a first metal region (210; 220) above the first surface (204a) of the semiconductor body (200; 204); a first dielectric layer (208) between the first metal region (210; 220) and the first surface (204a), wherein a parasitic capacitance (Cp; CpMOM) is established between the first metal region (210; 220) and the semiconductor body through the first dielectric layer (208); a buried region (205), having a first electrical conductivity (N), extending in the semiconductor body (200; 204) at a distance from the first surface (204a); an electrically insulating trench (203), extending in the semiconductor body (200; 204) starting from the first surface (204a) towards the buried region (205) along a direction (2), reaching and contacting the buried region (205), and completely surrounding a first intermediate portion (204′; 209) of the semiconductor body (200; 204) which is comprised between the first surface (204a) and the buried region (205) and is in direct electrical contact with the buried region (205), wherein the first intermediate portion (204′; 209) has a second electrical conductivity (P) opposite to the first electrical conductivity (N), and is electrically floating, and wherein the buried region (205) and the first intermediate portion (204′; 209) form a first junction capacitance (Cj′) in electrical series with the parasitic capacitance (Cp).

The buried region (205) is a doped region having a doping value comprised between 10¹⁶ and 10¹⁸ at/cm³, and the first intermediate portion (204′; 209) is a doped region having a doping value comprised between 10¹⁴ and 10¹⁶ at/cm³.

The first intermediate portion (204′; 209) has a thickness, between the first surface (204a) and the buried region (205) along said direction (z), between 0.5 μm and 2 μm.

The trench (203) includes at least one filling layer of insulating material which provides electrical insulation of the first intermediate portion (204′; 209) orthogonally to said direction (z).

The electronic device further includes a substrate (202), said semiconductor body (204) extending on the substrate (202), wherein the trench (203) extends in the semiconductor body up to reaching the substrate (202), completely surrounding a second intermediate portion (204″; 229) of the semiconductor body (204) between the buried region (205) and the substrate (202).

The second intermediate portion (204″; 229) has the second electrical conductivity (P), and the buried region (205) and the second intermediate portion (204″; 229) are in direct electrical contact with each other, so as to form a second junction capacitance (Cj″) in electrical series with the first junction capacitance (Cj′).

The buried region (205) has a top face (205a) facing the surface (204a), a bottom face (205b) opposite to the top face along said direction (2), and a lateral face which connects the top face (205a) to the bottom face (205b), and the trench (203) is in direct contact with the buried region (205) at the top face (205a) or, alternatively, at the lateral face.

The trench (203) completely or partially traverses the buried region (205).

The buried region (205) extends between the first (204′; 209) and the second (204″; 229) intermediate portions, electrically insulating them from each other.

The buried region (205) is electrically floating.

The electronic device further includes one or more conductive regions (216) extending in the first intermediate portion (204′; 209) between the first surface (204a) and the buried region (205), in electrical contact with the buried region (205); and one or more electrical contacts (218) in electrical connection with a respective conductive region (216), for providing an electrical bias to the buried region (205) through said respective one or more conductive regions.

The electronic device further includes a second metal region (212) above the first metal region (210), and a second dielectric layer (214) between the first and the second metal regions (210, 212), the first metal region (210), the second metal region (212) and the second dielectric layer (214) forming a galvanic isolator (21).

The first dielectric layer (208) accommodates at least in part a Metal-Oxide-Metal, MOM, type capacitor, said first metal region (210) being part of said MOM capacitor.

The electronic device further includes a metal shield (224) above, and at a distance from, the MOM capacitor and electrically insulated from the MOM capacitor, said metal shield (224) being biasable to ground voltage (GND).

A method for manufacturing an electronic device (20; 80), may be summarized as including the steps of: forming a buried region (205), having a first electrical conductivity (N), in a semiconductor body (200; 204) having a second electrical conductivity (P) opposite to the first electrical conductivity (N), the buried region (205) being formed at a distance from a surface (204a) of the semiconductor body and in direct electrical contact with the semiconductor body; forming, on the surface (204a) of the semiconductor body (200; 204), a first dielectric layer (208); forming a first metal region (210; 220) on the first dielectric layer (208), wherein a parasitic capacitance (Cp; CpMOM) is established between the first metal region (210; 220) and the semiconductor body through the first dielectric layer (208); forming an electrically insulating trench (203) in the semiconductor body (200; 204) starting from the surface (204a) towards the buried region (205), reaching the buried region (205) and completely surrounding an intermediate portion (204′; 209) of the semiconductor body (200; 204) comprised between the first surface (204a) and the buried region (205), said intermediate portion (204′; 209) having the second electrical conductivity (P), being electrically floating, and forming, with the buried region (205), a junction capacitance (Cj′) in electrical series with the parasitic capacitance (Cp; CpMOM).

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An electronic device, comprising:
a semiconductor body having a first surface;
a first metal region overlying the first surface of the semiconductor body;
a first dielectric layer between the first metal region and the first surface, the first metal region and the semiconductor body configured to form a parasitic capacitance between the first metal region and the semiconductor body through the first dielectric layer;
a buried region having a first electrical conductivity type and extending in the semiconductor body at a distance from the first surface;
an electrically insulating trench extending in the semiconductor body starting from the first surface towards the buried region along a direction, reaching and contacting the buried region, and completely surrounding a first intermediate portion of the semiconductor body, the first intermediate portion is positioned between the first surface and the buried region and is in direct electrical contact with the buried region,
wherein the first intermediate portion has a second electrical conductivity type opposite to the first electrical conductivity type, and is electrically floating, and
wherein the buried region and the first intermediate portion are configured to form a first junction capacitance in electrical series with the parasitic capacitance.

2. The electronic device according to claim 1, wherein:
the buried region is a doped region having a doping value between 10¹⁶ and 10¹⁸ at/cm³, and
the first intermediate portion is a doped region having a doping value between 10¹⁴ and 10¹⁶ at/cm³.

3. The electronic device according to claim 1, wherein the first intermediate portion has a thickness between the first surface and the buried region along the direction between 0.5 μm and 2 μm.

4. The electronic device according to claim 1, wherein the electrically insulating trench includes at least one filling layer of insulating material that provides electrical insulation of the first intermediate portion orthogonally to the direction.

5. The electronic device according to claim 1, further comprising:
a substrate, the semiconductor body extending on the substrate, the electrically insulating trench extending in the semiconductor body up to reaching the substrate, completely surrounding a second intermediate portion of the semiconductor body positioned between the buried region and the substrate.

6. The electronic device according to claim 5,
wherein the second intermediate portion has the second electrical conductivity type, and
wherein the buried region and the second intermediate portion are in direct electrical contact with each other, so as to form a second junction capacitance in electrical series with the first junction capacitance.

7. The electronic device according to claim 1,
wherein the buried region has a first face facing the first surface, a second face opposite to the first face along the direction, and a lateral face which connects the first face to the second face,
wherein the electrically insulating trench is in direct contact with the buried region at the first face orat the lateral face.

8. The electronic device according to claim 1, wherein the electrically insulating trench completely or partially traverses the buried region.

9. The electronic device according to claim 5, wherein the buried region extends between the first and the second intermediate portions, electrically insulating them from each other.

10. The electronic device according to claim 1, wherein the buried region is electrically floating.

11. The electronic device according to claim 1, further comprising:
one or more conductive regions extending in the first intermediate portion between the first surface and the buried region, and in electrical contact with the buried region; and
one or more electrical contacts in electrical connection with a respective conductive region, and configured to provide an electrical bias to the buried region through the respective one or more conductive regions.

12. The electronic device according to claim 1, further comprising:
a second metal region overlying the first metal region; and
a second dielectric layer between the first and the second metal regions,
the first metal region, the second metal region, and the second dielectric layer forming a galvanic isolator.

13. The electronic device according to claim 1, wherein the first dielectric layer accommodates at least in part a Metal-Oxide-Metal (MOM) type capacitor, the first metal region being part of the MOM capacitor.

14. The electronic device according to claim 13, further comprising:
a metal shield overlying and at a distance from the MOM capacitor, and electrically insulated from the MOM capacitor, the metal shield being biasable to ground voltage.

15. A method for manufacturing an electronic device, the method comprising:
forming a buried region, having a first electrical conductivity type, in a semiconductor body having a second electrical conductivity type opposite to the first electrical conductivity type, the buried region being formed at a distance from a surface of the semiconductor body and in direct electrical contact with the semiconductor body;
forming, on the surface of the semiconductor body, a first dielectric layer;
forming a first metal region on the first dielectric layer, a parasitic capacitance is established between the first metal region and the semiconductor body through the first dielectric layer;
forming an electrically insulating trench in the semiconductor body starting from the surface towards the buried region, reaching the buried region and completely surrounding an intermediate portion of the semiconductor body positioned between the surface and the buried region,
the intermediate portion having the second electrical conductivity type, being electrically floating, and forming, with the buried region, a junction capacitance in electrical series with the parasitic capacitance.

16. The method according to claim 15, wherein
the buried region is a doped region having a doping value between 10¹⁶ and 10¹⁸ at/cm³, and
the intermediate portion is a doped region having a doping value between 10¹⁴ and 10¹⁶ at/cm³.

17. The method according to claim 15, wherein the intermediate portion has a thickness between the surface and the buried region between 0.5 μm and 2 μm.

18. A device, comprising:
a structural layer including semiconductor material, the structural layer having a first surface;
a buried region in the structural layer and spaced from the first surface by a portion of the structural layer;
a trench including insulating material in the structural layer, the buried region and the trench surrounding the portion of the structural layer;
a dielectric layer on the first surface;
a first metal layer in the dielectric layer and spaced from the first surface; and
a second metal layer in the dielectric layer and spaced from the first metal layer.

19. The device of claim 18, wherein the buried region has a first electrical conductivity type, and the portion of the structural layer has a second electrical conductivity type opposite to the first electrical conductivity type.

20. The device of claim 18, further comprising:
an insulating layer extending into the first surface and the portion of the structural layer.
